(19) United States
(12) Patent Application Publication
(10) Pub. No.: US 2023/0311153 A1
(43) Pub. Date: Oct. 5, 2023

(54) SUBSTRATE PROCESSING APPARATUS

(71) Applicant: SEMES CO., LTD., Chungcheongnam-do (KR)

(72) Inventors: Sung Hun EOM, Chungcheongnam-do (KR); Tae Won YUN, Chungcheongnam-do (KR); Yun Hwa HONG, Chungcheongnam-do (KR); Jong Kook BAE, Chungcheongnam-do (KR)

(21) Appl. No.: 18/101,121

(22) Filed: Jan. 25, 2023

(30) Foreign Application Priority Data
Apr. 1, 2022 (KR) 10-2022-0041362

(51) Int. Cl. B05C 5/00; B05C 11/08; B05D 1/00

(52) U.S. Cl. CPC B05C 5/001; B05C 11/08; B05D 1/005

(57) ABSTRACT

A substrate processing apparatus, which may suppress occurrence of temperature deviation caused by an air current, is provided. The substrate processing apparatus includes a chamber including an upper body and a lower body and having a processing space formed therein by the upper body and the lower body, a substrate support unit disposed in the processing space and having a support surface on which the substrate is supported, a heater disposed to heat gas in the processing space, an introduction unit configured to supply gas toward an edge of the support surface, and a discharge unit configured to discharge the gas in the processing space. The discharge unit may include a plurality of outlets spaced apart from a centerline of the support surface in the upper body and disposed to be closer to the centerline of the support surface than to the introduction unit.

### CROSS-REFERENCE TO RELATED APPLICATION(S)

This application claims benefit of priority to Korean Patent Application No. 10-2022-0041362 filed on Apr. 1, 2022 in the Korean Intellectual Property Office, the disclosure of which is incorporated herein by reference in its entirety.

### BACKGROUND

### 1. Field

The present disclosure relates to a substrate processing apparatus, and more particularly, to a substrate processing apparatus for treating a substrate with heat.

### 2. Description of Related Art

Semiconductor manufacturing processes include a photolithography process in which a desired pattern is formed on a wafer. A photolithography process is performed in local spin coating equipment to which exposure equipment is connected to continuously perform an application process, an exposure process, and a developing process. Such spin coating equipment may sequentially or selectively perform an application process, a baking process, and a developing process.

In a baking process, a substrate is thermally treated using a baking chamber. Such a baking chamber for performing a thermal treatment and a substrate processing apparatus 1000 are illustrated in FIG. 1.

As illustrated in FIG. 1, the substrate processing apparatus 1000 includes a chamber 1100 including an upper body 1110 and a lower body 1120, a substrate support 1200 disposed inside the chamber 1100, a heater 1300 providing heat to the inside of the chamber 1100, an introduction unit 1400 supplying gas to the chamber 1100, and a discharge unit 1500 discharging gas inside the chamber 1100.

In a structure such as the substrate processing apparatus 1000 of FIG. 1, the discharge unit 1500 is disposed in a central portion of an internal surface of the upper body 1110 such that an air current is rapidly generated in a central portion of a substrate W when viewed from above. When such an air current is rapidly generated, temperature deviation occurs, resulting in a high possibility of occurrence of an error.
Patent Document 1: KR 10-2034914 B

### SUMMARY

An aspect of the present disclosure is to provide a substrate processing apparatus which may suppress occurrence of temperature deviations caused by an air current.

According to an aspect of the present disclosure, a substrate processing apparatus includes: a chamber including an upper body and a lower body and having a processing space formed therein by the upper body and the lower body; a substrate support unit disposed in the processing space and having a support surface on which the substrate is supported; a heater disposed to heat gas in the processing space; an introduction unit configured to supply gas toward an edge of the support surface; and a discharge unit configured to discharge the gas in the processing space. The discharge unit may include a plurality of outlets spaced apart from a centerline of the support surface in the upper body and disposed to be closer to the centerline of the support surface than to the introduction unit.

The plurality of outlets may have the same circular cross-section and may be disposed in positions spaced apart by the same distance from the centerline of the support surface.

The discharge unit may include four outlets, the outlets may be arranged at intervals of 90 degrees around the centerline of the support surface, a distance from a center of the outlet to the centerline of the support surface may correspond to half of a radius of the support surface, and a diameter of the circular cross-section may corresponds to the distance from a center of the outlet to the centerline of the support surface.

The outlet may include annular grooves formed around the centerline of the support surface, and distances from centerlines of the grooves to the centerline of the support surface may be different from each other in the plurality of outlets.

According to an aspect of the present disclosure, a substrate processing apparatus includes: a chamber including an upper body and a lower body and having a processing space formed therein by the upper body and the lower body; a substrate support unit disposed in the processing space and having a support surface supporting a substrate; a heater provided on the substrate support; a plurality of introduction units provided on the upper body and configured to supply gas to an edge of the support surface; a discharge unit configured to discharge the gas in the processing space; and a porous diffusion plate connected to the upper body and disposed in a position, downwardly spaced apart from the discharge unit. The discharge unit may be spaced apart from the centerline of the support surface in the upper body and may include a plurality of outlets disposed to be closer to the centerline of the support surface than to the introduction unit, a discharge pipe connected to a discharge device, and connection pipes connecting the plurality of outlets to the discharge pipe on an external side of the upper body. The plurality of outlets may have the same circular cross-section and are arranged at intervals of 360/N degrees around the centerline of the support surface in a position spaced apart by the same distance from the centerline of the support surface, where N is the number of outlets. The discharge pipe may be disposed on the centerline of the support surface, and the connection pipes are disposed to be symmetrical with each other.

According to an aspect of the present disclosure, a substrate processing apparatus includes: a chamber including an upper body and a lower body and having a processing space formed therein by the upper body and the lower body; a substrate support unit disposed in the processing space and having a support surface supporting a substrate; a heater provided on the substrate support unit; a plurality of introduction units provided on the upper body and configured to supply gas to an edge of the support surface; a discharge unit configured to discharge gas in the processing space; and a porous diffusion plate connected to the upper body and disposed in a position, downwardly spaced apart from the discharge unit. The discharge unit may be spaced apart from the centerline of the support surface in the upper body and may include a plurality of outlets disposed to be closer to the centerline of the support surface than to the introduction unit, a discharge pipe connected to a discharge device, and connection pipes connecting the plurality of outlets to the discharge pipe on an external side of the upper body. The outlet may include annular grooves formed around the centerline of the support surface, a gap between the grooves adjacent to each other may be constant, and the gap between the grooves may be equal to a distance from a centerline of the groove, closest to the centerline of the support surface, to the centerline of the support surface.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a schematic view of a substrate processing apparatus according to the related art.

FIG. 2A is a schematic plan view of a substrate processing apparatus.

FIG. 2B is a schematic view of the substrate processing apparatus of FIG. 2A when viewed in direction A-A.

FIG. 3 is a plan view of a substrate processing apparatus according to an embodiment of the present disclosure.

FIG. 4 is a cross-sectional view taken along line I-I of the substrate processing apparatus of FIG. 3.

FIG. 5 is a schematic bottom view of an upper body of the substrate processing apparatus of FIG. 3.

FIG. 6 is a plan view of a substrate processing apparatus according to another embodiment of the present disclosure.

FIG. 7A is a plan view of a substrate processing apparatus according to another embodiment of the present disclosure, FIG. 7B is a partially enlarged view of a plan view of the substrate processing apparatus of FIG. 7A, and FIG. 7C is a view illustrating a modified example of the substrate processing apparatus of FIG. 7B.

FIG. 8 is a cross-sectional view taken along line II-II of the substrate processing apparatus of FIG. 7A.

FIG. 9 is a plan view of a substrate processing apparatus according to another embodiment of the present disclosure.

FIG. 10 is a cross-sectional view of a substrate processing apparatus according to another embodiment of the present disclosure.

FIG. 11 is a cross-sectional view of a substrate processing apparatus according to another embodiment of the present disclosure.

FIG. 12 is a cross-sectional view of a substrate processing apparatus according to another embodiment of the present disclosure.

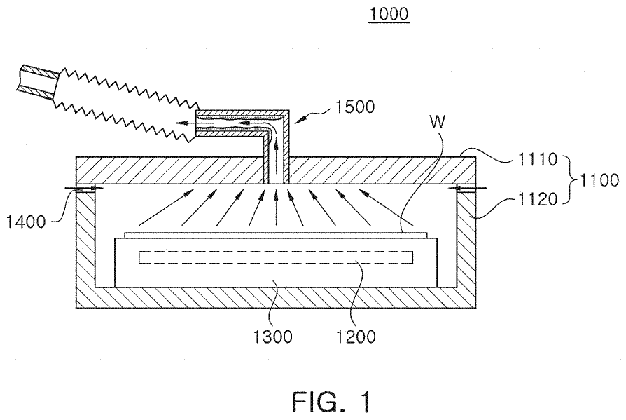

### DETAILED DESCRIPTION

Hereinafter, preferred embodiments will be described in detail such that those of ordinary skill in the art could easily practice the present disclosure with reference to the accompanying drawings. However, in describing a preferred embodiment of the present disclosure in detail, if it is determined that a detailed description of a related known function or configuration unnecessarily obscures the gist of the present disclosure, the detailed description thereof will be omitted. In addition, the same reference numerals may be used throughout the drawings for parts having similar functions and operations. In addition, in this specification, terms such as ‘on,’ ‘upper portion,’ ‘upper surface,’ ‘below,’ ‘lower portion,’ ‘lower surface,’ ‘side surface,’ and the like may be based on the drawings, and in fact, may be changed depending on a direction in which components is disposed.

In addition, throughout the specification, when a portion is ‘connected’ to another portion, may include not only ‘directly connected.’ but also ‘indirectly connected’ to other components interposed therebetween. In addition, ‘including’ a certain component means that other components are further included, rather than excluding other components, unless otherwise stated.

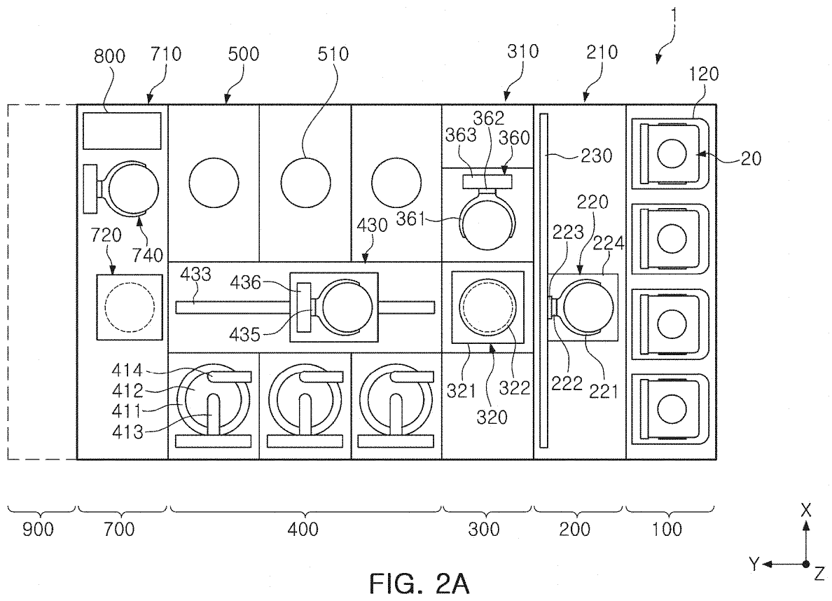

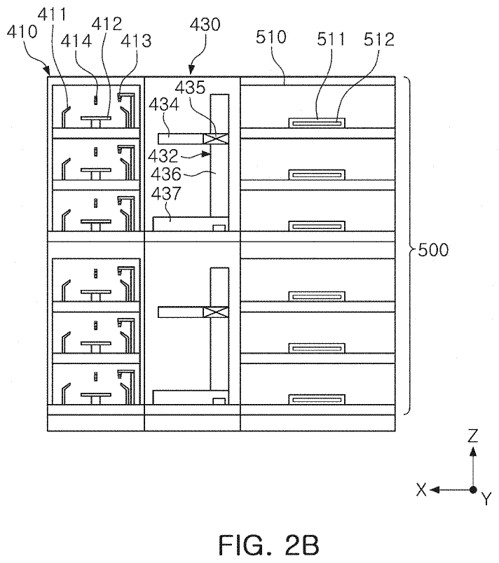

FIGS. 2A and 2B are schematic views of a substrate processing apparatus 1 according to an embodiment. FIG. 2A is a schematic view of the substrate processing apparatus 1 when viewed from above, and FIG. 2B is a schematic view of the substrate processing apparatus of FIG. 2A when viewed in direction A-A.

Referring to FIGS. 2A and 2B, the substrate processing apparatus 1 may include a load port 100, an index module 200, a buffer module 300, an application and developing module 400, and a purge module 800. The load port 100, the index module 200, the buffer module 300, the application and developing module 400, and an interface module 700 may be sequentially arranged in a line in one direction. The purge module 800 may be provided in the interface module 700. Alternatively, the purge module 800 may be provided in various positions such as a position to which an exposure apparatus on a rear end of the interface module 700 is connected, a side portion of the interface module 700, and the like.

Hereinafter, a direction in which the load port 100, the index module 200, the buffer module 300, the application and developing module 400, and the interface module 700 are arranged will be referred to as a first direction Y, when viewed from above, a direction perpendicular to the first direction Y when viewed from above will be referred to as a second direction X, and a direction perpendicular to the first direction Y and the second direction X will be referred to as a third direction Z.

A substrate W may be moved while being accommodated in a cassette 20. The cassette 20 may have a structure sealed from the outside. As an example, a front open unified pod (FOUP) having a door on a front side may be used as the cassette 20.

Hereinafter, the load port 100, the index module 200, the buffer module 300, the application and developing module 400, the interface module 700, and the purge module 800 will be described in detail.

The load port 100 has a carrier 120 on which the cassette 20, in which the substrates W are accommodated, is disposed. A plurality of carriers 120 may be provided, and may be disposed in the second direction X in a row. In FIG. 2A, an example in which four carriers 120 are provided is illustrated, but the number of the carriers 120 is not limited thereto.

The index module 200 may transfer a substrate W between the cassette 20, disposed on the carrier 120 of the load port 100, and the buffer module 300. The index module 200 may have a frame 210, an index robot 220, and a guide rail 230. The frame 210 may be provided to have a substantially hollow cuboidal shape and may be disposed between the load port 100 and the buffer module 300. The frame 210 of the index module 200 may be provided to have a height, lower than a height of a frame 310 of the buffer module 300. The index robot 220 and the guide rail 230 may be disposed in the frame 210. The index robot 220 may be provided such that a hand 221, directly handling a substrate W, is movable and rotatable in the first direction 12, the second direction 14, and the third direction 16. The index robot 220 may have a hand 221, an arm 222, a support 223, and a prop 224. The hand 221 may be fixedly installed in the arm 222. The arm 222 may be provided to have a flexible and rotatable structure. The support 223 may be configured such that a length direction thereof is disposed in the third direction Z. The arm 222 may be coupled to the support 223 to be movable along the support 223. The support 223 may be fixedly coupled to the prop 224. The guide rail 230 may be provided such that a length direction thereof is disposed in the second direction X. The prop 224 may be coupled to the guide rail 230 to be linearly movable along the guide rail 230. Although not illustrated, the frame 210 may be further provided with a door opener opening and closing a door of the cassette 20.

The buffer module 300 may include a frame 310, a buffer 320, and a buffer robot 360. The frame 310 may be provided to have a hollow cuboidal shape, and may be disposed between the index module 200 and the application and developing module 400. The buffer 320 and the buffer robot 360 may be disposed in the frame 310. The buffer robot 360 may be spaced apart from the buffer 320 by a predetermined distance in the second direction X.

The buffer 320 may temporarily store a plurality of substrates W. The housing 321 of the buffer 320 may have an opening in a direction, in which the buffer robot 360 is provided, and a direction in which an application unit robot 432 disposed in an application module is provided.

The buffer robot 360 may transfer a substrate W to the buffer 320. The buffer robot 360 may include a hand 361, an arm 362, and a support 363. The hand 361 may be fixedly installed on the arm 362. The arm 362 may be provided to have a flexible structure, allowing the hand 361 to be movable in the second direction X. The arm 362 may be coupled to the support 363 to be linearly movable along the support 363 in the third direction Z. The buffer robot 360 may be provided such that the hand 361 is driven only by two axes in the second direction X and the third direction Z.

The application module may perform a process of applying a photosensitive liquid such as a photoresist to the substrate W and a heat treatment process of, for example, heating and cooling the substrate W before and after the photoresist applying process. The application module 401 may have an application chamber 410, a baking chamber unit 500, and a transfer chamber 430. The application chamber 410, the transfer chamber 430, and the chamber unit 500 may be sequentially disposed in the second direction X. For example, with respect to the transfer chamber 430, the application chamber 410 may be provided on one side of the transfer chamber 430 the baking chamber unit 500 may be provided on the other side of the transfer chamber 430.

A plurality of application chambers 410 may be provided, and a plurality of application chambers 410 may be provided in each of the first direction Y and the third direction Z. The baking chamber unit 500 may include a plurality of baking chambers 510, and a plurality of the plurality of baking chambers 510 may be provided in each of the first direction Y and the third direction Z. The transfer chamber 430 may be disposed to be parallel to the first buffer 320 of the first buffer module 300 in the first direction Y. The application unit robot 432 and the guide rail 433 may be disposed in the transfer chamber 430. The transfer chamber 430 may have a substantially rectangular shape. The application unit robot 432 may transfer the substrate W between the baking chamber 510, the application chamber 410, and the buffer 320 of the buffer module 300.

The guide rail 433 may be disposed such that a length direction thereof is parallel to the first direction Y. The guide rail 433 may guide the application unit robot 432 to linearly move in the first direction Y. The application unit robot 432 may include a hand 434, an arm 435, a support 436, and a prop 437. The hand 434 may be fixedly installed on the arm 435. The arm 435 may be provided to have a flexible structure, allowing the hand 434 to be movable in a parallel direction. The support 436 may be provided such that a length direction thereof is disposed in the third direction Z. The arm 435 may be coupled to the support 436 to be linearly movable along the support 436 in the third direction Z. The support 436 may be fixedly coupled to the prop 437, and the prop 437 may be coupled to the guide rail 433 to be movable along the guide rail 433.

All of the application chambers 410 may have the same structure, but the types of chemical solutions used in the respective application chambers 410 may be different from each other. The chemical may be a chemical for formation of a photoresist layer or an antireflection layer.

The application chamber 410 may be configured to apply a chemical to a substrate W. The application chamber 410 may include a cup 411, a substrate support 412, and a nozzle 413. The cup 411 may have an open top shape. The substrate support 412 may be disposed in the cup 411 and may support the substrate W. The substrate support 412 may be provided to be rotatable. The nozzle 413 may supply the chemical to the substrate W placed on the substrate support 412. The chemical may be applied to the substrate W by a spin coat method. The application chamber 410 may be further provided with a nozzle 414, supplying a cleaning solution such as deionized water (DIW) to clean a surface of the substrate W on which the chemical is applied, and a back rinsing nozzle, not illustrated, cleaning a lower surface of the substrate W.

The baking chamber 510 may include a substrate support 511 and a heater 512 inside a substrate support unit 511, and may treat the substrate W with heat when the substrate W is seated on the substrate support unit 511 by the application unit robot 432.

The interface module 700 may connect the application and developing module 400 to an external exposure apparatus 900. The interface module 700 may include an interface frame 710, an interface buffer 720, and a transfer robot 740, and the transfer robot 740 may transfer a substrate, transferred to the interface buffer 720 after processes of the application and developing module 400 are terminated, to the exposure apparatus 900. The interface buffer 720 may include a housing and a support, and the transfer robot 740 and the application unit robot 432 may carry the substrate W into or out of the support 722.

The present disclosure provides an improved baking chamber 510 in the above-described substrate processing apparatus 1, and an embodiment to be described later may be applied to the improved baking chamber 510 of the substrate processing apparatus 1. However, the present disclosure is not limited thereto, and may be configured as an additional facility. Hereinafter, the baking chamber 510 may also be referred to as a substrate processing apparatus 1000.

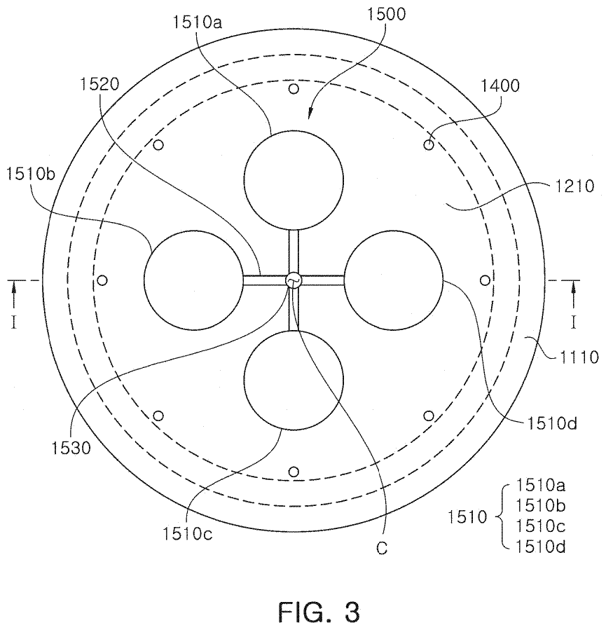

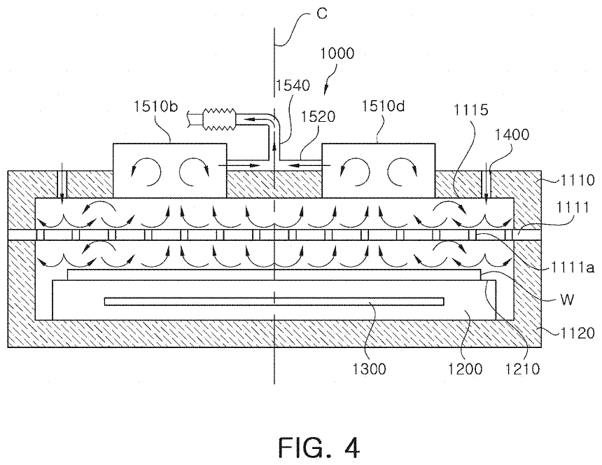

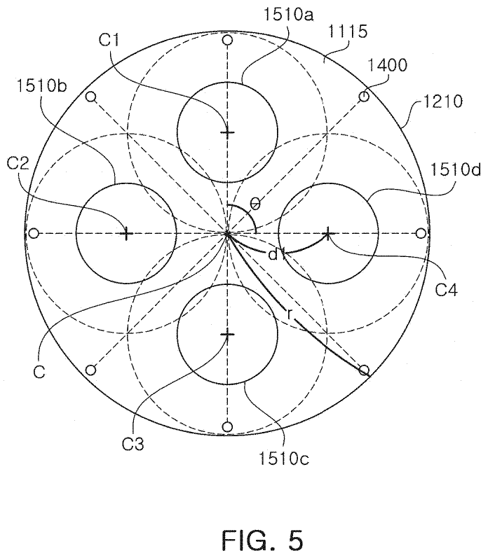

The substrate processing apparatus 1000 according to an embodiment will be described with reference to FIGS. 3 to 5. FIG. 3 is a plan view of the substrate processing apparatus according to an embodiment, FIG. 4 is a cross-sectional view taken along line I-I of the substrate processing apparatus of FIG. 3, and FIG. 5 is a schematic view of the substrate processing apparatus of FIG. 3.

As illustrated in FIGS. 3 and 4, the substrate processing apparatus 1000 according to an embodiment may include a chamber 1100 including an upper body 1110 and a lower body 1120 and having a processing space 1130 formed therein by the upper body 1110 and the lower body 1120, a substrate support unit 1200 disposed in the processing space 1130 and having a support surface 1210 on which the substrate W is supported, a heater 1300 disposed to heat gas in the chamber 1100, an introduction unit 1400 configured to supply gas toward an edge of the support surface 1210, and a discharge unit 1500 configured to discharge gas in the processing space 1130, and the discharge unit 1500 may include a plurality of outlets 1510 be spaced apart from a centerline C of the support surface 1210 in the upper body 1110 and disposed to be closer to the centerline C of the support surface 1210 than the introduction unit 1400.

The chamber 1100 may include the upper body 1110 and the lower body 1120, and a transfer robot, for example, an application unit robot 432 of FIG. 2A may seat a substrate W on the support surface 1210 of the substrate support unit 1200 disposed on the lower body 1120. The upper body 1110 may have a shape of a cylinder having an open lower surface, and the lower body 1120 may have a shape of a cylinder having an open upper surface. The upper body 1110 may cover the lower body 1120, and may have a processing space 1130 formed therein.

The introduction unit 1500 and the discharge unit 1400 may be disposed in the upper body 1110, and the lower body 1120 has a substrate support 1200 may be disposed in the lower body 1120.

A porous diffusion plate 1111 may be disposed on the upper body 1110 in a position, downwardly spaced apart from the discharge unit 1500. The porous diffusion plate 1111 may be a plate having a plurality of through-holes 1111a formed therein, and gas may be changed to have a uniform flow while passing through the porous diffusion plate 1111. Accordingly, the gas from the introduction unit 1400 may flow to the processing space 1130 on a side of the substrate support unit 1200 after passing through the porous diffusion plate 1111. The flow of the gas may be uniformly distributed to the porous diffusion plate 1111 without being distributed directly below the introduction unit 1400. Similarly, the gas in the processing space 1130 on the side of the substrate support 1200 may be exhausted through the discharge unit 1500 after passing through the porous diffusion plate 1111.

The substrate support unit 1200 may have a support surface 1210 on which the substrate W is seated, and the support surface 1210 may have a circular shape around the centerline C, as illustrated in FIG. 3. A heater 1300 may be disposed inside the substrate support 1200, and may provide uniform heat to the substrate W, seated on the substrate support unit 1200, such that a center is disposed on the centerline C of the support surface 1210, thereby treating the substrate W with the heat.

The introduction unit 1400 may be disposed on the upper body 1110 to be directed toward the edge of the substrate support 1200. In the present embodiment, the introduction unit 1400 may be formed in a vertical direction, and may be disposed on an upper portion in a vertical direction in a position outside the substrate W of the support surface 1210. Accordingly, the introduction unit 1400 may be disposed just inside an edge of the support surface 1210, as illustrated in FIGS. 3 and 5. As described above, the introduction unit 1400 may be disposed to be directed toward the edge of the support surface 1210, so that a cold air current starts from the outside of the substrate W to reduce a temperature deviation in an internal portion of the substrate W.

For example, the introduction unit 1400 may be directed toward a region between edges of the support surface 1210 from the outside of the substrate W, on the support surface 1210 of the substrate support 1200.

The introduction unit 1400 may include a plurality of introduction holes spaced apart from each other at regular intervals at a predetermined distance with respect to the centerline C. The number of introduction units 1400 is not limited, and the introduction units 1400 may be structured to be connected to each other.

The discharge unit 1500 may include a plurality of outlets 1510 spaced apart from the centerline C of the support surface 1210 in the upper body 1110 and disposed to be closer to the centerline C of the support surface 1210 than the introduction unit 1400, a discharge pipe 1530 connected to an external discharge device, and a connection pipe 1520 connecting the plurality of outlets 1510 to the discharge pipe 1530 on an external side of the upper body 1110.

In the present embodiment, the plurality of outlets 1510 may have the same circular cross-section and may be disposed in positions spaced apart from the centerline C of the support surface 1210 by the same distance. For example, the first to fourth outlets 1510a, 1510b, 1510c, and 1510d may be formed to have circular cross-sections, respectively having centers C1, C2, C3, and C4. The centers C1, C2, C3, and C4 have the same distance d1 from the centerline C of the support surface 1210. In addition, radii of the circular cross-sections of the first to fourth outlets 1510a, 1510b, 1510c, and 1510d are all the same.

In addition, the first to fourth outlets 1510a, 1510b, 1510c, and 1510d may be disposed apart from each other by the same distance d1 at the same angle θ with respect to the centerline C. As illustrated in FIGS. 3 and 5, the first to fourth outlets 1510a, 1510b, 1510c, and 1510d may be respectively disposed at centers of regions divided with respect to the centerline C of the support surface 1210. In the present embodiment, the first to fourth outlets 1510a, 1510b, 1510c, and 1510d are respectively disposed at the centers of the four divided regions, so that the first to fourth outlets 1510a, 1510b, 1510c, and 1510d may be spaced apart from each other by 90 degrees.

A distance from the centers C1, C2, C3, and C4 of the outlet 1510 to the centerline C of the support surface may correspond to half of a radius “r” of the support surface 1210, and a diameter of the circuit cross-section of the outlet 1510 may correspond to a distance “d1” from the centers C1, C2, C3, and C4 of the outlet 1510 to the centerline C of the support surface 1210. For example, a diameter of the circular cross-section of the outlet 1510 may correspond to half of the radius “r” of the support surface 1210.

Since a flow rate (m³/s) is the product of the cross-sectional area (m²) and a flow velocity (m/s), the cross-sectional area of the outlet 1510 may be increased in the present embodiment, so that the flow velocity may be reduced at the same flow rate. For example, an exhaust cross-section is increased four times as compared with the case in which a single outlet 1510 is provided, so that the flow velocity may be decreased to ¼ and an effect caused by the flow velocity may be reduced.

In addition, since the outlet 1510 is disposed in the center of the divided region, gas may be uniformly exhausted to each outlet 1510 and a temperature deviation in the processing space 1130 may be reduced.

The outlet 1510 may be connected to a discharge pipe 1530 through a connection pipe 1520 and the discharge pipe 1530 may be connected to a gas suction means, for example, a discharge means, and thus an air current may be formed through the outlet 1510. The discharge pipe 1530 may be disposed at the centerline C of the support surface 1210 and the connection pipe 1520 may be symmetrically connected to the outlet 1510 to symmetrically, for example, uniformly generate an air current at each outlet 1510.

In the embodiment of FIGS. 3 to 5, the outlet 1510 has been described as including four outlets 1510, but the number of the outlets 1510 of the discharge unit 1500 is not limited to four in the present embodiment.

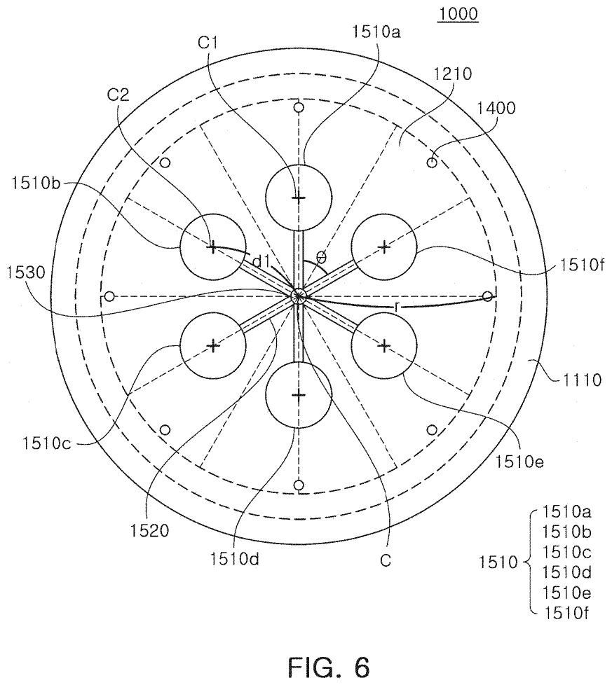

A plan view according to another embodiment of the present disclosure is illustrated in FIG. 6.

Similarly to the substrate processing apparatus 1000 of FIGS. 3 to 5, a substrate processing apparatus 1000 of FIG. 6 may include a chamber 1100 including an upper body 1110 and a lower body 1120 and having a processing space 1130 formed therein by the upper body 1110 and the lower body 1120, a substrate support unit 1200 disposed in the processing space 1130 and having a support surface 1210 on which the substrate W is supported, a heater 1300 disposed to heat gas in the chamber 1100, an introduction unit 1400 configured to supply gas toward an edge of the support surface 1210, and a discharge unit 1500 configured to discharge gas in the processing space 1130, and the discharge unit 1500 may include a plurality of outlets 1510 be spaced apart from a centerline C of the support surface 1210 in the upper body 1110 and disposed to be closer to the centerline C of the support surface 1210 than an edge of the support surface 1210.

In the embodiment of FIG. 6, the discharge unit 1500 may include six outlets 1510, for example, first to sixth outlets 1510a, 1510b, 1510c, 1510d, 1510e, and 1510f. Centers of the first to sixth outlets 1510a, 1510b, 1510c, 1510d, 1510e, and 1510f may be spaced apart from each other by the same distance d1 from the centerline C of the support surface 1210 at an interval of a predetermined angle θ. In the present embodiment, the outlet 1510 may have a circular cross-section and a diameter of the circular cross-section of the outlet 1510 is smaller than that in the embodiment of FIGS. 3 to 5, so that the diameter may be greater than the distance d1.

In the present disclosure, the number of outlets 1510 may be three or more. In this case, an angle at which the outlets 1510 is disposed from the centerline C may be 360/N degrees (where N is the number of outlets).

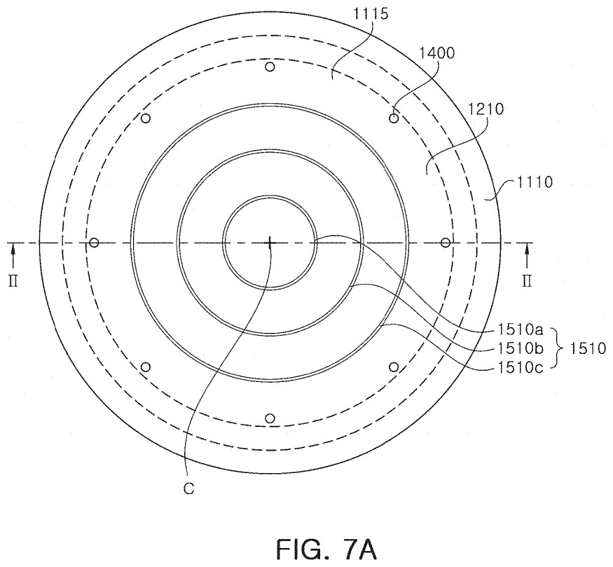

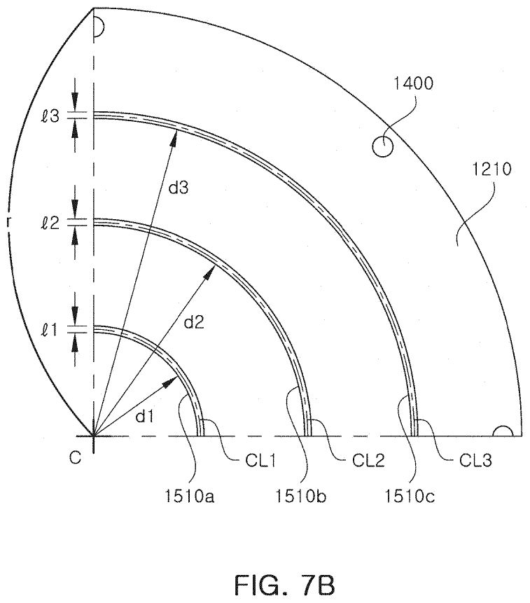

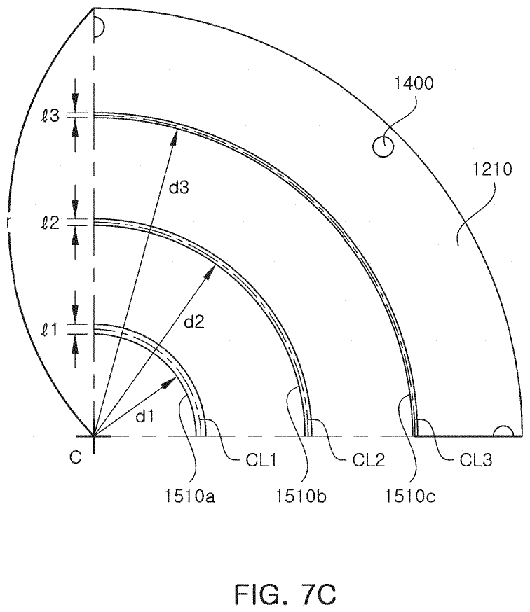

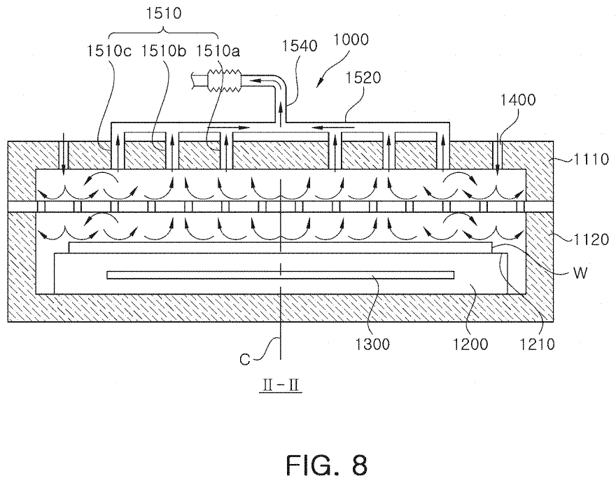

Another embodiment of the present disclosure is illustrated in FIGS. 7A and 7B, a modified embodiment of FIG. 7B is illustrated in FIG. 7C, and a cross-sectional view taken along line II-II of the embodiment of FIGS. 7A and 7B is illustrated in FIG. 8.

As illustrated in FIGS. 7A, 7B, and 8, a substrate processing apparatus 1000 of the present embodiment may include a chamber 1100 including an upper body 1110 and a lower body 1120 and having a processing space 1130 formed therein by the upper body 1110 and the lower body 1120, a substrate support unit 1200 disposed in the processing space 1130 and having a support surface 1210 supporting the substrate W, a heater 1300 provided on the substrate support 1200, a plurality of introduction units 1400 provided on the upper body 1210 and configured to supply gas to an edge of the support surface 1210, a discharge unit 1500 configured to discharge the gas in the processing space 1130, and a porous diffusion plate 1111 connected to the upper body 1110 and disposed in a position, downwardly spaced apart from the discharge unit 1500.

The chamber 1100 may include the upper body 1110 and the lower body 1120, and a transfer unit may seat the substrate W on the support surface 1210 of the substrate support 1200 disposed on the lower body 1120 while the upper body 1110 is opened. The upper body 1110 may have a shape of a cylinder having an open lower surface, and the lower body 1120 may have a shape of a cylinder having an open upper surface. The upper body 1110 may cover the lower body 1120 and may have a processing space 1130 formed therein.

The discharge unit 1500 and the introduction unit 1400 may be disposed on the upper body 1110, and the substrate support unit 1200 may be disposed in the lower body 1120.

A porous diffusion plate 1111 may be disposed in a position, downwardly spaced apart from the discharge unit 1500 formed on an internal upper surface 1115. The porous diffusion plate 1111 may be a plate in which a plurality of through-holes 1111a are formed, and gas may be changes to have a uniform flow while passing through the porous diffusion plate 1111.

The substrate support 1200 may have a support surface 1210 on which the substrate W is seated, and the support surface 1210 may have a circular shape around the centerline C. A heater 1300 may be disposed inside the substrate support 1200, and may provide uniform heat to the substrate W, seated on the substrate support unit 1200, such that a center is disposed on the centerline C of the support surface 1210, thereby treating the substrate W with the heat.

The introduction unit 1400 may be disposed on the upper body 1110 to be directed toward the edge of the substrate support 1200. In the present embodiment, the introduction unit 1400 may be formed in a vertical direction, and may be disposed on an upper portion in a vertical direction in a position outside the substrate W of the support surface 1210. The introduction unit 1400 may have a plurality of introduction holes arranged at regular intervals from the centerline C at a predetermined distance.

The discharge unit 1500 may be spaced apart from the centerline C of the support surface 1210 in the upper body 1110, and may include a plurality of outlets 1510 disposed to be closer to the centerline C of the support surface 1210 than the introduction unit 1400, a discharge pipe 1530 connected to a discharge device, and a connection pipe 1520 connecting the plurality of outlets 1510 to the discharge pipe 1530 on an external side of the upper body 1110.

The plurality of outlets 1510 may be formed around the centerline C of the support surface 1210 and may be a plurality of annular grooves having different distances from the centerline C. For example, a first outlet 1510a may be an annular groove having a first distance d1 from the centerline C, a second outlet 1510b may be an annular groove having a second distance d2 from the centerline C, and the third outlet 1510c may be an annular groove having a third distance d1 from the centerline C. The distance from the centerline C or from one groove to another groove may be based on centerlines CL1, CL2, CL3 of the groove.

The first to third outlets 1510a, 1510b, and 1510c may be annular grooves spaced apart from each other at regular intervals. For example, a distance from the centerline C to the centerline CL1 of the first outlet 1510a may be equal to a distance from the center line CL1 of the first outlet 1510a to the center line CL2 of the second outlet 1510b and a distance from the center line CL2 of the second outlet 1510b to the center line CL3 of the third outlet 1510a, and may be equal to a quarter of a radius “r” of the support surface 1210. For example, even in the present embodiment, the first to third outlets 1510a, 1510b, and 1510c may be formed to be uniform from the center of the supporting surface 1210, and a uniform air current may be generated by the first to third outlets 1510a, 1510b, and 1510c.

The first to third outlets 1510a, 1510b, and 1510c may have the same groove width. For example, a width 11 of a groove of the first outlet 1510a, a width 12 of a groove of the second outlet 1510b, and a width 13 of a groove of the third outlet 1510c may be the same, and each of the widths 11, 12, and 13 of the grooves may be about 10 mm. Accordingly, an area of a cross-section, through which gas is allowed to flow by the first to third outlets 1510a, 1510b, and 1510c, may be larger than that in the related art (in which only one outlet is formed in a center), so that a temperature gradient may be reduced at a low flow velocity.

The discharge pipe 1530 may be connected to a position of the centerline C, and the connection pipe 1520 may be symmetrically connected to the discharge pipe 153 while connecting the first to third outlet ports 1510a, 1510b, and 1510c to each other, so that a gas flow may be formed to be uniform in each outlet 1510.

A modified example of the embodiment of FIG. 7B is illustrated in FIG. 7C. In the case of FIG. 7c, components are the same as those of FIG. 7B except for the widths 11, 12, and 13 of the first to third outlets 1510a, 1510b, 1510c, and the descriptions thereof will be omitted.

As illustrated in the modified example of FIG. 7C, widths 11, 12, and 13 of first, second, and third outlets 1510a, 1510b, and 1510c may be increased as a distance from a centerline C is decreased. For example, the width 11 of the first outlet 1510a may be greater than the width 12 of the second outlet 1510b, and the width 12 of the second outlet 1510b may be greater than the width 13 of the third outlet 1510c (11>12>13). Since a length of a groove is decreased in a direction toward a center of a substrate W, the width of the groove may be increased to compensate for this. In addition, since a more uniform flow may be formed as cross-sectional areas of the first to third outlets 1510a, 1510b, and 1510c become similar to each other, a flow of an air current may be stabilized.

When the outlet 1510 includes an annular groove, the number of annular grooves is not limited as long as the annular grooves is provided in plural.

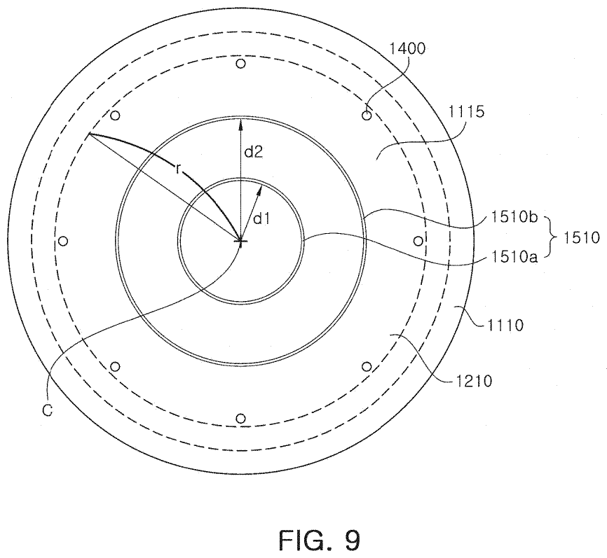

A plan view of another embodiment of the present disclosure is illustrated in FIG. 9. As illustrated in FIG. 9, when an outlet 1510 is provided with an annular groove, the outlet 1510 may include two outlets 1510a and 1510b. In this case, a distance d1 from a centerline C to the first outlet 1510a may be equal to half of a distance d2 from the centerline C to the second outlet 1510b. For example, the distance d1 from the centerline C to the first outlet 1510a may be equal to a distance from the first outlet 1510a to the second outlet 1510b, and the distance may be equal to one-third (⅓) of a radius “r” of the support surface 1210. When the outlet 1510 is formed to have an annular groove, a distance between the outlets 1510 and a distance between the outlet 1510, closest to the centerline C, and the centerline C may be equal to 1/(N+1) of a radius of the support surface 1210, where N is the number of outlets.

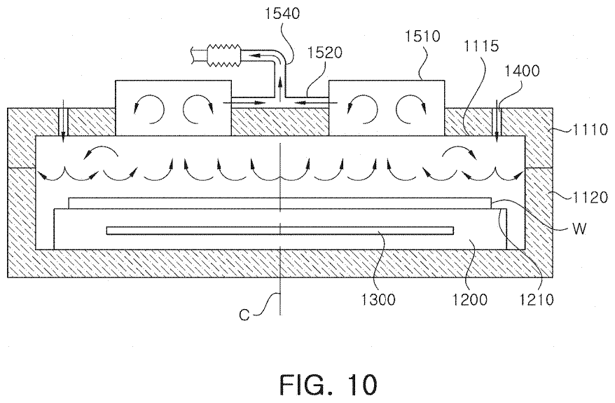

A cross-sectional view of another embodiment of the present disclosure is illustrated in FIG. 10.

As illustrated in FIG. 10, a substrate processing apparatus 1000 may include a chamber 1100 including an upper body 1110 and a lower body 1120 and having a processing space 1130 formed therein by the upper body 1110 and the lower body 1120, a substrate support unit 1200 disposed in the processing space 1130 and having a support surface 1210 supporting the substrate W, a heater 1300 disposed to heat gas in the processing space, an introduction unit 1400 configured to supply gas to an edge of the support surface 1210, a discharge unit 1500 configured to discharge the gas in the processing space 1130. A configuration of the discharge unit 1500 may be the same as that in the embodiment of FIGS. 3 to 5 and may not include a porous diffusion plate 1111, unlike the embodiment of FIGS. 3 to 5. In this case, a uniform flow effect caused by the porous diffusion plate 1111 may be slightly reduced, but a flow velocity in the processing space 1130 may be reduced due to the configuration of the discharge unit 1500, and thus a temperature deviation caused by the flow velocity may be reduced. In addition, an air current in the processing space 1130 may be improved due to a plurality of outlets 1510 and an arrangement thereof to generate a uniform flow in the processing space 1130.

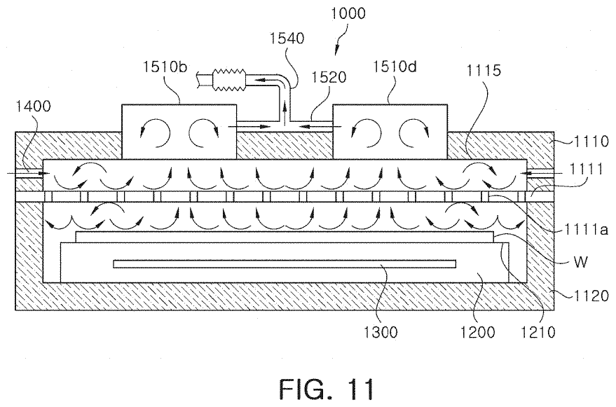

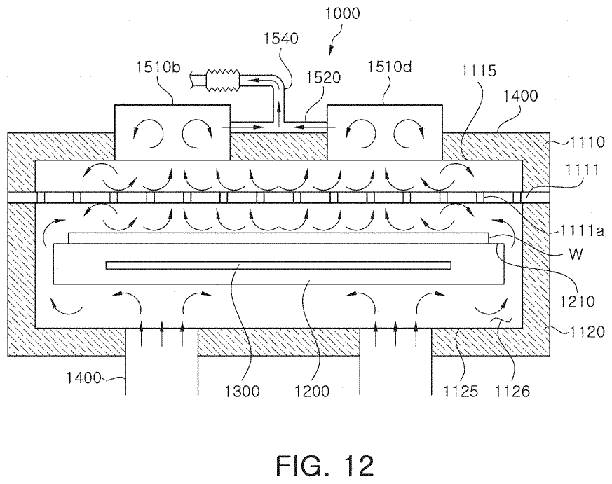

In the present disclosure, the introduction unit 1400 may not be provided on an upper surface of the upper body 1110. Another embodiment of the present disclosure is illustrated in FIGS. 11 and 12.

In FIG. 11, in a substrate processing apparatus 1000 having the same structure as that in FIGS. 3 to 5, an introduction unit 1400 may be formed on a side surface of an upper body 1110. In FIG. 12, in a substrate processing apparatus 1000 having the same structure as that in FIGS. 3 to 5, an introduction unit 1400 may be formed on a lower surface 1125 of a lower body 1120. Accordingly, as illustrated in the drawings, gas introduced from the introduction unit 1400 may be introduced through a lower space 1126 of the substrate support unit 1200, and may then be introduced into an edge of the substrate support unit 1200 around the substrate support unit 1200. As in the embodiment illustrated in FIG. 11 or FIG. 12, in the case of the introduction unit 1400, the gas may be introduced by any method as long as the gas is introduced toward an edge of the support surface 1210.

As described above, occurrence of temperature deviation caused by an air current may be suppressed through a substrate processing apparatus.

While example embodiments have been shown and described above, it will be apparent to those skilled in the art that modifications and variations could be made without departing from the scope of the present disclosure as defined by the appended claims.

What is claimed is:

1. A substrate processing apparatus comprising:
a chamber including an upper body and a lower body and having a processing space formed therein by the upper body and the lower body;
a substrate support unit disposed in the processing space and having a support surface on which the substrate is supported;
a heater disposed to heat gas in the processing space;
an introduction unit configured to supply gas toward an edge of the support surface; and
a discharge unit configured to discharge the gas in the processing space,
wherein
the discharge unit comprises a plurality of outlets spaced apart from a centerline of the support surface in the upper body and disposed to be closer to the centerline of the support surface than to the introduction unit.

2. The substrate processing apparatus of claim 1, wherein
the plurality of outlets have the same circular cross-section and are disposed in positions spaced apart by the same distance from the centerline of the support surface.

3. The substrate processing apparatus of claim 2, wherein
the discharge unit comprises a discharge pipe, connected to a discharge device, and connection pipes connecting the plurality of outlets to the discharge pipe on an external side of the upper body.

4. The substrate processing apparatus of claim 2, wherein
the discharge unit comprises at least three outlets, and
the plurality of outlets are arranged at intervals of 360/N degrees around the centerline of the support surface,
where N is the number of outlets.

5. The substrate processing apparatus of claim 4, wherein
a distance from a center of the outlet to the centerline of the support surface corresponds to half of a radius of the support surface.

6. The substrate processing apparatus of claim 2, wherein
the discharge unit comprises four outlets,
the outlets are arranged at intervals of 90 degrees around the centerline of the support surface,
a distance from a center of the outlet to the centerline of the support surface corresponds to half of a radius of the support surface, and
a diameter of the circular cross-section corresponds to the distance from a center of the outlet to the centerline of the support surface.

7. The substrate processing apparatus of claim 3, wherein
The discharge pipe is disposed on the centerline of the support surface, and the connection pipes are disposed to be symmetrical with each other.

8. The substrate processing apparatus of claim 1, wherein
the outlet comprises annular grooves formed around the centerline of the support surface, and
distances from centerlines of the grooves to the centerline of the support surface are different from each other in the plurality of outlets.

9. The substrate processing apparatus of claim 8, wherein
a gap between centerlines of the grooves adjacent to each other is constant, and
the gap between the centerlines of the grooves is equal to a distance from a centerline of a groove, closest to the centerline of the support surface, to the centerline of the support surface.

10. The substrate processing apparatus of claim 9, wherein
the discharge portion includes three annular grooves,
a gap between centerlines of the grooves adjacent to each other corresponds to a quarter of a radius of the substrate, and
a width of the groove is increased in a direction toward the center of the support surface.

11. The substrate processing apparatus of claim 1, wherein
the introduction unit includes a plurality of introduction holes formed to extend from the upper body toward an edge of the support surface.

12. The substrate processing apparatus of claim 11, wherein
the plurality of introduction holes are arranged at equal intervals at the same distance from the centerline of the support surface.

13. The substrate processing apparatus of claim 1, further comprising:
a porous diffusion plate connected to the upper body and disposed in a position, downwardly spaced apart from the discharge unit.

14. The substrate processing apparatus of claim 1, wherein
the introduction unit is provided in the lower body.

15. A substrate processing apparatus comprising:
a chamber including an upper body and a lower body and having a processing space formed therein by the upper body and the lower body;
a substrate support unit disposed in the processing space and having a support surface supporting a substrate;
a heater provided on the substrate support;
a plurality of introduction units provided on the upper body and configured to supply gas to an edge of the support surface;
a discharge unit configured to discharge the gas in the processing space; and
a porous diffusion plate connected to the upper body and disposed in a position, downwardly spaced apart from the discharge unit,
wherein
the discharge unit is spaced apart from the centerline of the support surface in the upper body and comprises a plurality of outlets disposed to be closer to the centerline of the support surface than to the introduction unit, a discharge pipe connected to a discharge device, and connection pipes connecting the plurality of outlets to the discharge pipe on an external side of the upper body,
the plurality of outlets have the same circular cross-section and are arranged at intervals of 360/N degrees around the centerline of the support surface in a position spaced apart by the same distance from the centerline of the support surface, where N is the number of outlets, and
the discharge pipe is disposed on the centerline of the support surface, and the connection pipes are disposed to be symmetrical with each other.

16. The substrate processing apparatus of claim 15, wherein
the introduction unit comprises a plurality of introduction holes formed to extend from the upper body toward an edge of the support surface.

17. The substrate processing apparatus of claim 16, wherein
the discharge unit comprises four outlets,
the four outlets are arranged at intervals of 90 degrees around the centerline of the support surface,
a distance from a center of the outlet to the centerline of the support surface corresponds to half of a radius of the substrate, and
a diameter of the circular cross-section corresponds to the distance from the center of the outlet to the centerline of the support surface.

18. A substrate processing apparatus comprising:
a chamber including an upper body and a lower body and having a processing space formed therein by the upper body and the lower body;
a substrate support unit disposed in the processing space and having a support surface supporting a substrate;
a heater provided on the substrate support unit;
a plurality of introduction units provided on the upper body and configured to supply gas to an edge of the support surface;
a discharge unit configured to discharge gas in the processing space; and
a porous diffusion plate connected to the upper body and disposed in a position, downwardly spaced apart from the discharge unit,
wherein
the discharge unit is spaced apart from the centerline of the support surface in the upper body and comprises a plurality of outlets disposed to be closer to the centerline of the support surface than to the introduction unit, a discharge pipe connected to a discharge device, and connection pipes connecting the plurality of outlets to the discharge pipe on an external side of the upper body,
the outlet comprises annular grooves formed around the centerline of the support surface,
a gap between the grooves adjacent to each other is constant, and
the gap between the grooves is equal to a distance from a centerline of the groove, closest to the centerline of the support surface, to the centerline of the support surface.

19. The substrate processing apparatus of claim 18, wherein
the discharge unit comprises three annular holes, and
the gap of the groove adjacent to each other corresponds to a quarter of a radius of the substrate.

20. The substrate processing apparatus of claim 19, wherein
the introduction unit comprises a plurality of introduction holes formed to extend from the upper body toward an edge of the support surface, and
the plurality of introduction holes are arranged at equal intervals at the same distance from the centerline of the support surface.
